(19) United States
(12) Patent Application Publication
(10) Pub. No.: US 2025/0372904 A1
(43) Pub. Date: Dec. 4, 2025

(54) 3D PRINTED BRIDGES FOR PRINTED INTERCONNECTS

(71) Applicants: Daniel Hines, Chelmsford, MA (US); Alkim Akyurtlu-Ext, Arlington, MA (US); Christopher R. Areias, Londonderry, NH (US); Andrew M. Luce, Lowell, MA (US)

(72) Inventors: Daniel Hines, Chelmsford, MA (US); Alkim Akyurtlu-Ext, Arlington, MA (US); Christopher R. Areias, Londonderry, NH (US); Andrew M. Luce, Lowell, MA (US)

(21) Appl. No.: 18/680,353

(22) Filed: May 31, 2024

(51) Int. Cl. H01R 13/03; H01R 12/62; H01R 12/70; H01R 12/71; H01R 43/16

(52) U.S. Cl. CPC H01R 13/03; H01R 12/62; H01R 12/7076; H01R 12/718; H01R 43/16

(57) ABSTRACT

A bridge structure extending between a PCB contact pad and a component contact pad is provided. The bridge structure has a first polymer layer extending from a top surface of the PCB contact pad along with a second polymer layer extending from the first UV curable layer opposite the PCB contact pad. The bridge structure has a third polymer layer extending from the second layer opposite the first UV curable polymer layer to the component contact pad. A conductive interconnect is formed on the polymer layers and contacts the PCB contact pad and the component contact pad. Each of the polymer layers are ultraviolet (UV) curable and are illuminated with a UV light source that is spot focused. The polymer layers are formed to have a stepwise configuration where each polymer layer is cured prior to formation of the next polymer layer.

### TECHNICAL FIELD

Examples relate to printed circuit board (PCB) interconnects and more specifically to structure for interconnecting a PCB contact pad with a component contact pad.

### BACKGROUND

A PCB may include components, such as bare dies, disposed on a surface of the PCB and/or within cavities of the PCB to provide functionality for a device using the PCB. In order to electrically connect the components to traces at the PCB, electrically conductive paths need to be formed that connect contact pads at the trace to contact pads at the components, or connect contact pads at a component to connect contact pads at another component as in a multi-chip module (MCM). For components that are disposed on the PCB surface, the component contact pads may or may not be planar with the PCB contact pads. Moreover, for components that are within cavities of the PCB, a moat separates the component contact pads from the PCB contact pads. Furthermore, for MCMs, chips could be separated by a gap or chasm.

Therefore, structures need to be formed on the PCB that connect the PCB contact pads with the component contact pads. For implementations where the component extends from the PCB surface, a smooth transition in the form of a dielectric fillet needs to be formed around an edge of the component. The smooth transition needs to extend from the PCB surface to a top of the component. For implementations where the component is disposed within a cavity of the PCB, the moat that separates the component from the PCB needs to be filled with a smooth transition, again in the form of dielectric.

Problems can arise with the formation of the smooth transition fillet or the smooth transition moat fill. Both the smooth transition fillets and the moat fills can expand and contract during thermal cycling. During expansion and contraction, both the smooth transition fillets and the moat fills can cause cracking of the electrically conductive path between the PCB contact pads and the component contact pads. Furthermore, since the smooth transition moat fill is disposed within the PCB cavity and between the PCB and the component, expansion can cause cracking of both the PCB and the component due to the stresses placed on both the PCB and component during expansion of the smooth transition moat fill.

### BRIEF DESCRIPTION OF DRAWINGS

FIGS. 1A-1C illustrate, by way of example, a device that implements a bridge structure, in accordance with examples.

FIG. 2 shows horizontal and vertical overlaps that bridge structures, such as the bridge structure of FIG. 1, can incorporate, in accordance with examples.

FIG. 3 shows a method for forming the bridge structure of FIG. 1, in accordance with examples.

FIG. 4 illustrates an alternative example of a bridge structure, in accordance with examples.

FIGS. 5-8 illustrate various examples of bridge structures that can be used to connect a PCB contact pad with a component contact pad for a component disposed in a moat of a PCB, in accordance with examples.

### DETAILED DESCRIPTION

The following description and the drawings sufficiently illustrate teachings to enable those skilled in the art to practice them. Other embodiments may incorporate structural, logical, electrical, process, and other changes. Portions and features of some examples may be included in, or substituted for, those of other examples. Teachings set forth in the claims encompass all available equivalents of those claims.

Examples relate to a bridge structure that can extend between a PCB contact pad and a component contact pad for a digital device or a RF device. A conductive interconnect can be formed on the bridge structure between the PCB contact pad and the component contact pad. The conductive interconnect can contact both the PCB contact pad and the component contact pad and therefore provide electrical connection between the PCB contact pad and the component contact pad. The bridge structure can be configured such that an airgap is formed underneath the bridge structure, thereby improving performance of the digital/RF device.

The bridge structure can be a three-dimensional (3D) dielectric structure formed with a photopolymer that is capable of being deposited via a syringe, or either an aerosol-jet or ink-jet process performed with a direct-write printer. The bridge structure can be formed with an ultra-violet (UV) curable polymer. In addition to forming the bridge structure from a UV curable polymer, the bridge structure can be formed with a thixotropic ink capable of holding a shape upon deposition. The bridge structure can be formed to have a stepwise configuration where individual layers of the bridge structure are individually formed and then cured with spot focusing UV illumination at each step. A first layer is deposited near one of the PCB contact pad and the component contact pad. The first layer is deposited and then cured with spot focusing UV illumination. A second layer is then deposited either on a portion of the first layer or next to the first layer and then cured with spot focusing UV illumination. This process can be repeated for subsequent layers until the bridge structure extends to, or near, the other of the PCB contact pad and the component contact pad.

Once the bridge structure is formed, the conductive interconnect can be formed from a conductive ink and deposited onto the bridge structure. The conductive interconnect can be formed such that the conductive interconnect extends between the PCB contact pad and the component contact pad and contacts each of the PCB contact pad and the component contact pad thereby electrically coupling the PCB contact pad with the component contact pad. The bridge structure can have a width that is the same as a width of the conductive interconnect. In addition, the bridge structure can have any type of stepped configuration that facilitates bridging between the PCB contact pad and the component contact pad. Examples can include a curved configuration and a linear configuration.

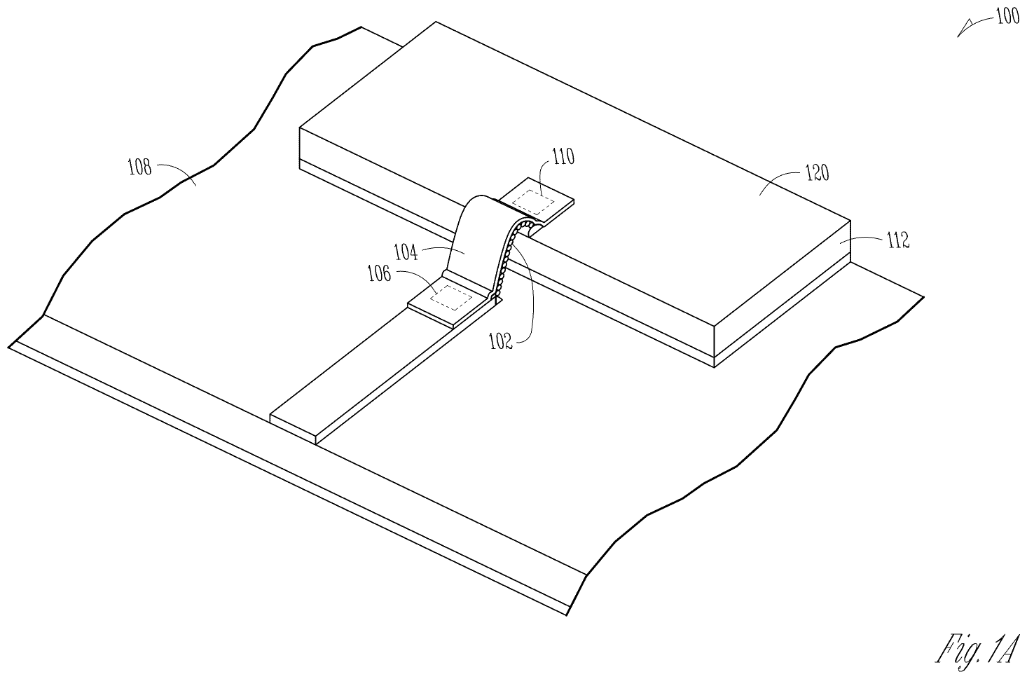

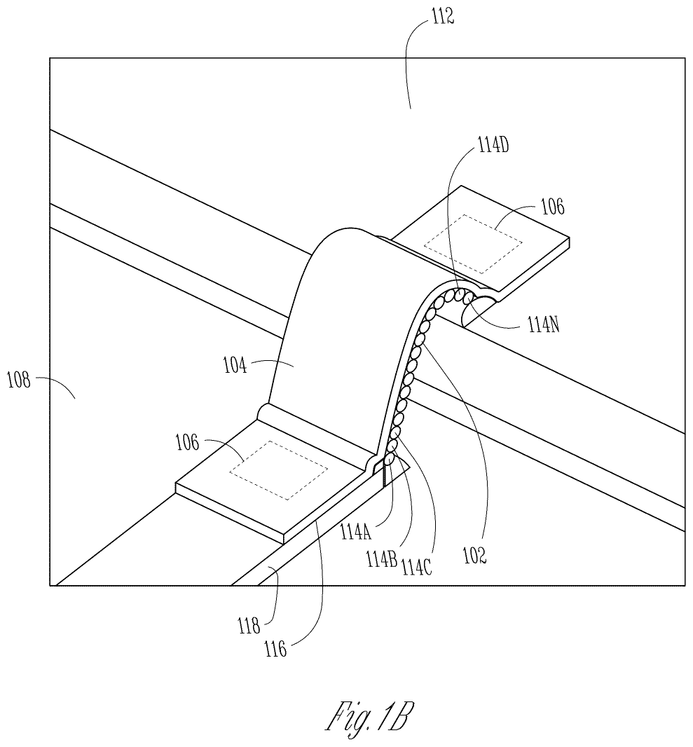

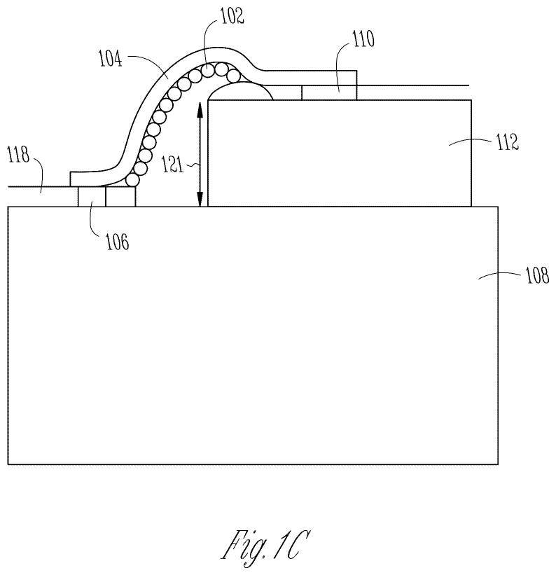

Now making reference to FIGS. 1A-1C, a device 100 is shown that can implement a bridge structure 102 that supports a conductive interconnect 104. The conductive interconnect 104 can function to electrically couple a PCB contact pad 106 of a PCB 108 with a component contact pad 110 of a component 112. The conductive interconnect 104 can be formed from any type of conductive material, such as aluminum, copper, silver, or the like. The conductive interconnect 104 can be formed such that each of the PCB contact pad 106 and the component contact pad 110 have direct contact with each other via the conductive interconnect 104.

The bridge structure 102 can be formed such that the conductive interconnect 104 can be printed onto the bridge structure 102 after formation of the bridge structure 102. The bridge structure 102 can include layers 114a-n formed from a UV curable polymer. The UV layers 114a-n can extend between edges of the PCB 118 and the component 112. The UV curable polymer can be any type of polymer that is capable of being 3D printed and then cured with a UV process. Examples of a UV curable polymer that can be used can include Norlandυ Electronic Adhesive NEA 121 available from Norland™M Products located in Jamesburg, New Jersey. Thus, the layers 114a-n can be a dielectric formed with a 3D printing process.

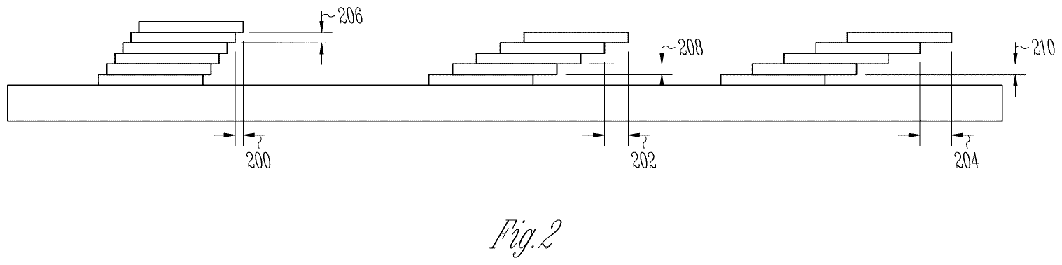

The UV curable polymer for the layers 114a-n can be selected as a function of various parameters. These parameters can include a relationship between cure intensity and a print speed of the layers 114a-n with a surface roughness of the dielectric when the UV curable polymer is printed. For example, for a low roughness surface, a combination of cure intensity and print speed can be selected that can allow partial curing of the layers 114a-n mid-print. Moreover, a ratio of horizontal overlap 200-204 (FIG. 2) to vertical overlap 206-210 (FIG. 2) along with a UV cure intensity, a UV curable polymer layer deposition rate, and a print speed are parameters that can be used in selecting a material for the UV curable polymer for the layers 114a-n. In examples, the horizontal overlaps 200-204 along with the vertical overlaps 206 can be varied for a single bridge structure such that the bridge structure 102 can have different shapes. These different shapes can include a structure that can linearly extend from the PCB conductive trace top surface 116 to the component top surface 120, a looped configuration that can extend from the PCB conductive trace top surface 116 to the component top surface 120, or any other shape.

The layers 114a-n can be individually formed where a first layer of the layers 110a-n is formed on the PCB conductive trace top surface 116 followed by a second layer of the layers 114a-n being formed on the first layer of the layers 114a-n. A third layer of the layers 114a-n can be formed on the second layer of the layers 114a-n. This process can be repeated for each of the layers 114a-114n. The layers 114a-n can be formed such that the first layer 114a of the layers 114a-n can extend from a top surface 116 of a PCB conductive trace 118. Moreover, the layers 114a-n can be formed such that a layer 114n of the layers 114a-n can extend to a top surface 120 of the component 112 thereby forming the bridge structure 102 having a looped configuration. Furthermore, the layer 114n can be higher than the layer 114a as shown with reference to FIGS. 1A-1C. Once the layers 114-n are formed to extend from the PCB conductive trace top surface 116 to the component top surface 120, the conductive interconnect 104 can be formed onto the bridge structure 102. The conductive interconnect 104 can be formed such that the conductive interconnect 104 extends beyond the layer 104a, over a portion of the PCB 108, and contacts the PCB contact pad 106 as shown with reference to FIGS. 1A-1C. The conductive interconnect 104 can also be formed such that the conductive interconnect 104 extends beyond the layer 104n, over a portion of the component 112, and contacts the component contact pad 110, also as shown with reference to FIGS. 1A-1C. Moreover, the bridge structure 102 can be formed such that an airgap 121 can be formed underneath the bridge structure 102 as shown in FIG. 1C. The airgap 121 can provide the benefits discussed above.

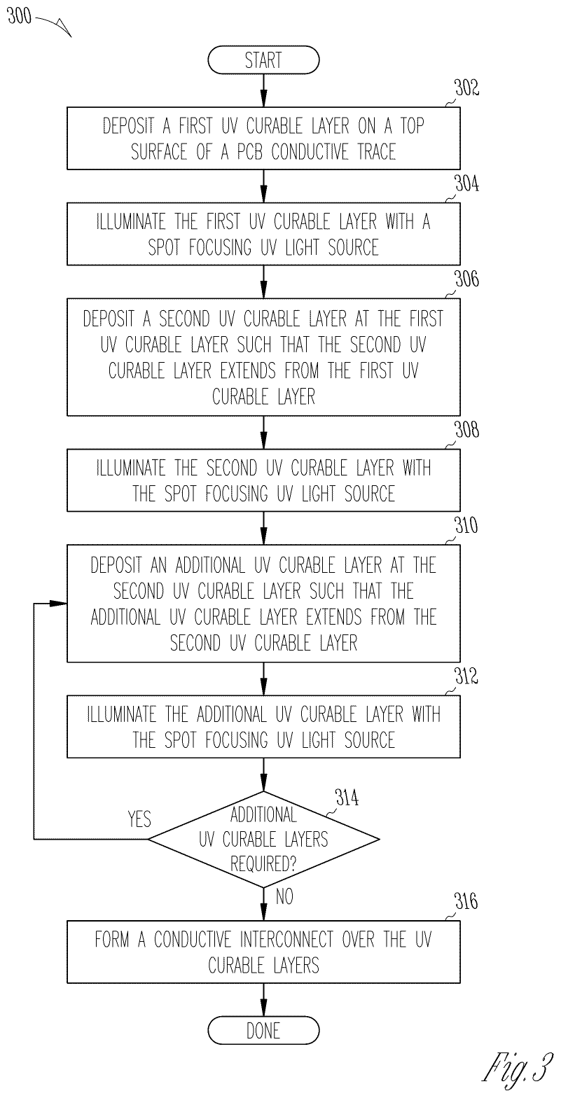

As an example of forming the bridge structure 102 with the layers 114a-n, reference is made to FIG. 3 and a method 300. During an operation 302, a first UV curable layer can be deposited onto a top surface of a PCB conductive trace. Once the first UV curable layer is deposited onto the PCB conductive trace top surface, the first UV curable layer can be illuminated with a spot focusing UV light source during an operation 304 in order to cure the first UV curable layer. The UV light source can be any type of illuminator capable of emitting UV light. Examples can include light emitting diodes (LED), incandescent light sources, halogen light sources, and the like. A lens can be placed at the UV light source which can function to focus the light emitted from the UV light source to an area having specific dimensions that can correspond to the layer being cured, such as the layers 114a-n, as they are being individually cured. For example, if the layers 114a-n have an area of one millimeter by one millimeter, the lens can focus light emitted from the UV light source to the area of one millimeter by one millimeter. This is in contrast to using a flood expose system, where the entire PCB along with the component could be exposed to the light emitted from the UV light source.

As an illustration of the method 300 and referred to herein as “the illustration,” making reference to FIG. 1B, during the operation 302, the layer 104a of the layers 114a-n can be deposited onto the PCB conductive trace top surface 116. After deposition, the layer 114a can be illuminated with a spot focusing UV light source as described above. Thus, only the layer 114a is exposed to light emitted from the spot focusing UV light source or only minimal areas outside of the layer 114a along with the layer 114a are illuminated with the light emitted from the UV light source during the operation 304 thereby curing the layer 114a.

Returning to FIG. 3 and the method 300, after the first UV curable layer is illuminated, an operation 306 is performed where a second UV curable layer can be deposited at the first UV curable layer. During the operation 306, the second UV curable layer can be deposited such that second UV curable layer extends from the first UV curable layer and opposite a PCB contact pad of a PCB. Moreover, the second UV curable layer can be deposited such that the UV curable layer has a horizontal overlap along with a vertical overlap as described above. After the second UV curable layer is deposited at the first UV curable layer, the second UV curable layer can be illuminated with a spot focusing UV light source in order to cure the second UV curable layer as discussed above during an operation 308.

Once the second UV curable layer is deposited and cured during the operations 306 and 308, the method performs an operation 310 where an additional UV curable layer can be deposited at the second UV curable layer opposite the first UV curable layer. During the operation 310, the additional UV curable layer can be deposited such that the additional UV curable layer extends from the second UV curable layer. In some examples, the additional UV curable layer deposited during the operation 308 can be the last UV curable layer deposited when the additional UV curable layer can contact a top surface of the component, such as the component top surface. In these examples, during the operation 310, in addition to depositing the additional UV curable layer such that the additional UV curable layer extends from the second UV curable layer, the additional UV curable layer can be deposited such that the additional UV curable layer can contact a component top surface.

Similar to the second UV curable layer, the additional UV curable layer can be deposited such that the additional UV curable layer has a horizontal overlap along with a vertical overlap as described above. In examples, the additional UV curable layer can have the same horizontal and vertical overlaps as the second UV curable layer. Alternatively, the additional UV curable layer can have a horizontal overlap that is different than the horizontal overlap of the second UV curable layer while the second and additional UV curable layers have the same vertical overlaps. In addition, the second and additional UV curable layers can have the same horizontal overlaps while having different vertical overlaps. In further examples the second UV curable layer can have different horizontal and vertical overlaps in comparison to the additional UV curable layer.

After the additional UV curable layer is deposited during the operation 308, the method 300 can perform an operation 312. During the operation 312, the additional UV curable layer can be illuminated with a spot focusing UV light source in order to cure the second UV curable layer as discussed above.

Returning to the illustration, during the operation 306, a layer 114b can be deposited at the first layer 114a and extend from the layer 114a and opposite the PCB contact pad 110. The layer 114b can be deposited such that the layer 114b has the horizontal overlap 200 and the vertical overlap 208 relative to the layer 114a. After deposition, the layer 114b can be illuminated with the spot focusing UV light source used to cure the layer 114a during the operation 308. After the layer 114b is cured during the operation 308 in the illustration, a layer 114c can be deposited at the layer 114b such that the layer 114c extends from the layer 114b during the operation 312. The layer 114c can be deposited such that the layer 114c has the horizontal overlap 204, which is different from the horizontal overlap 200 of the layer 114a and the vertical overlap 208, which is the same as the vertical overlap of the layer 114a. After the layer 114c is deposited, the layer 114c can be illuminated with the spot focusing UV light source used to cure the layers 114a and 114b in order to cure the layer 114c during the operation 312. It should be noted that while spot curing is discussed, example envision any type of UV curing, such as in-situ UV curing where the UV source is on at the same time as the printed polymer ink is deposited on the print surface. Moreover, curing can include scenarios where a delay occurs between ink deposition and UV curing along with scenarios inks can be used that are not UV curing but can be in-situ processed using alternative methods while at the same time holding their as-deposited shape.

Turning attention back to FIG. 3 and the method 300, during an operation 314, the method 300 can determine if additional UV curable layers should be deposited. This determination can be based on whether or not the additional UV curable layer deposited during the operation 312 contacts the component top surface thereby completing a bridge structure. If a determination is made that additional UV curable layers need to be deposited during the operation 314, the operations 310-314 can be repeated until a UV curable layer contacts the component top surface and a bridge structure is completed.

When a determination is made that a bridge structure has been completed and no additional UV curable layers are necessary, the method 300 can perform an operation 316, where a conductive interconnect can be formed over the UV curable layers and the completed bridge structure. During the operation 316, the conductive interconnect can be deposited onto the bridge structure. As mentioned above, the conductive interconnect can be formed such that the conductive interconnect extends between the PCB contact pad and the component contact pad and contacts each of the PCB contact pad and the component contact pad thereby electrically coupling the PCB contact pad with the component contact pad.

Returning to the illustration along with FIGS. 1A and 1B, during the operation 314, a determination can be made that additional UV curable layers are required. Thus, the operations 310-314 are repeated until the layer 114n is formed. In the illustration, the layer 114n can be formed such that the layer 114n extends from a layer 114d to the component top surface 120 thereby forming the bridge structure 102.

Once the layer 114n is cured during the operation 312, since the layer 114n extends to and contacts the component top surface 120, during the operation 314, the method 300 determines that no additional UV curable layers are required. As such, during the operation 316, the conductive interconnect 104 can be deposited onto the bridge structure 102 using any deposition technique. Techniques can include using a printing device where the printing device uses a pen to deposit the conductive interconnect 104 onto the bridge structure 102. The conductive interconnect 104 can also be direct write printed onto the bridge structure 102 using any suitable printing process. Moreover, the conductive interconnect 104 ink can be 3D printed onto the bridge structure 102. In the illustration, the conductive interconnect 104 can have the same width as the bridge structure 102.

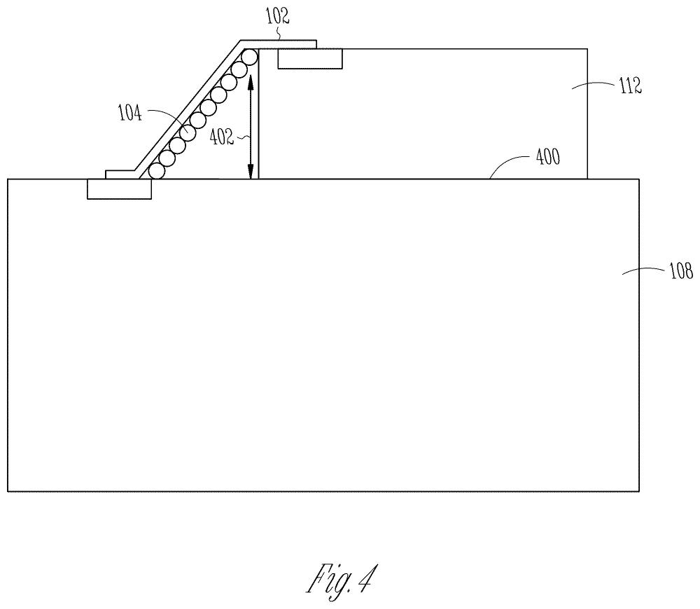

In FIGS. 1A and 1B, the bridge structure 102 was shown as having a looped configuration. In addition to the looped configuration, when the component 112 is formed on a top surface 400 of the PCB 108, the bridge structure 102 can have a linear configuration that can approximate a straight line, as shown with reference to FIG. 4. Here, the layers 104a-n can be formed in accordance with the techniques described above to have the configuration shown with reference to FIG. 4. In the configuration of FIG. 4, the bridge structure 102 can be formed such that an airgap 402 can be formed underneath the bridge structure 102. The airgap 402 can provide the benefits discussed above.

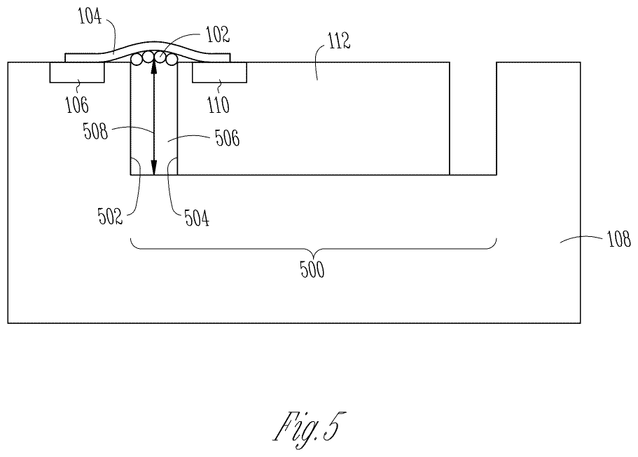

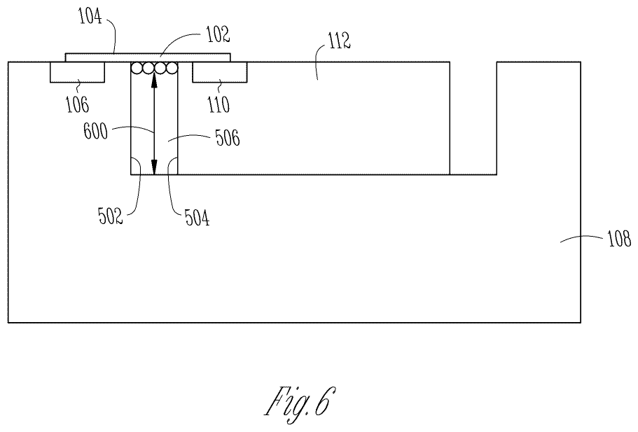

In further examples, instead of having the component 112 at the PCB top surface 400, the component 112 can be formed in a cavity 500 of the PCB 108 as shown in FIG. 5. An edge 502 of the PCB 108 formed by the PCB cavity 500 can be separated from an edge 504 of the component 112 by a moat 506. The bridge structure 102 can be formed over the moat 506 in order to allow the conductive interconnect 104 to electrically couple the PCB contact pad 106 with the component contact pad 110. The bridge structure 102 along with the conductive interconnect 104 can be formed as discussed above. Here, the bridge structure 102 can be formed to extend between the PCB edge 502 and the component edge 504. In FIG. 5, the bridge structure 102 is shown as having a looped configuration that extends between the PCB edge 502 and the component edge 504. In further examples, the bridge structure 102 can have the linear configuration described above and shown in FIG. 6. Regardless of the configuration of the bridge structure 102 in examples where the PCB 108 includes the PCB cavity 500, the bridge structure 102 can be formed as described above. Moreover, the bridge structure 102 can be formed such that an airgap 508 (FIG. 5) or an airgap 600 (FIG. 6) can be formed underneath the bridge structure 102. The airgaps 508 and 600 can provide the benefits discussed above.

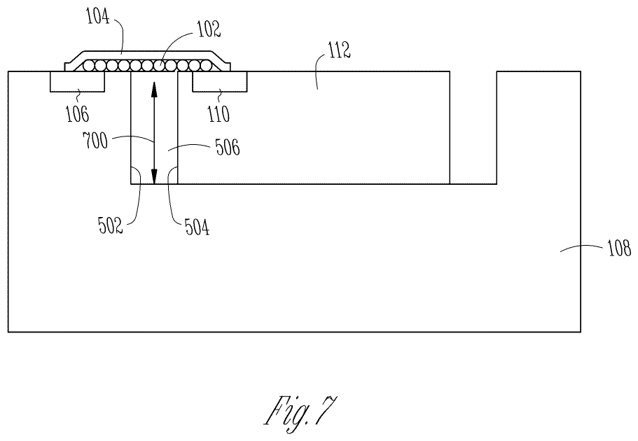

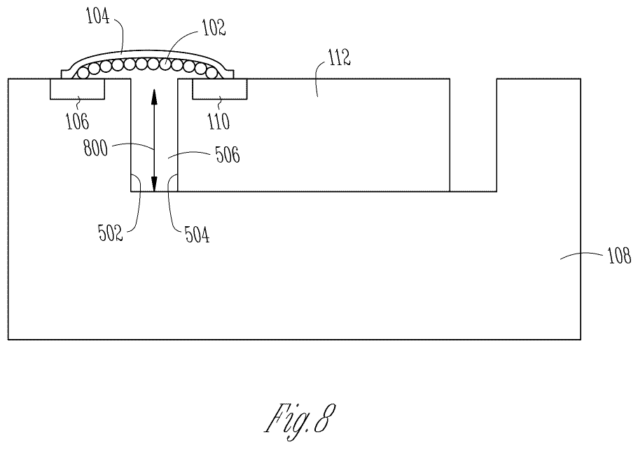

In further examples where the component 112 is disposed within the PCB cavity 500, the bridge structure 102 can be formed to extend at a position before the PCB edge 500 and past the component edge 504, as shown with reference to FIGS. 7 and 8. Moreover, the bridge structure 102 can be formed in the linear configuration (FIG. 7) or the looped configuration (FIG. 8) as described above. In FIGS. 7 and 8, the bridge structure 102 can be formed such that an airgap 700 (FIG. 7) or an airgap 800 (FIG. 8) can be formed underneath the bridge structure 102. The airgaps 508 and 600 can provide the benefits discussed above. Moreover, in the examples of FIGS. 7 and 8, the layer 114a can be planar with the layer 114n in contrast to the example in FIGS. 1A-1C, where the layer 114n can be higher than the layer 114a.

In FIGS. 4-8, while the PCB contact pad 106 is shown as being disposed within the PCB 108 and the component contact pad 110 is shown as being disposed within the component 112, in examples where the component 112 is disposed within the PCB cavity 500, each of the PCB contact pad 106 and the component contact pad 110 can have the configuration shown with reference to FIGS. 1A-1C.

In addition, while looped and linear configuration have been described herein, the bridge structure 102 can have any configuration that can be dependent on various parameters, such as a height difference between the PCB conductive trace top surface 116 and the component top surface 120 or a width of the moat 506.

Examples also envision scenarios where non-PCB surfaces include printed circuitization deposited on an arbitrary surface and are to be electrically connected to a component that is either surface mounted nearby or placed into a nearby cavity as discussed above. Here, the bridge structure 102 can be formed to connect the printed circuitization deposited on an arbitrary surface to a component or a PCB contact pad using the methodologies as discussed herein.

### ADDITIONAL EXAMPLES

Example 1 is a bridge structure that extends between a contact pad a printed circuit board (PCB) at a conductive trace of the PCB and a contact pad of a component disposed on the PCB, the bridge structure comprising: a first ultra-violet (UV) curable polymer layer extending from a top surface of the conductive trace at the PCB contact pad; a second UV curable polymer layer extending from the first UV curable polymer layer opposite the PCB contact pad, the second UV curable polymer layer being formed on the first UV curable polymer layer after the first UV curable polymer layer is cured with UV illumination; a third UV curable polymer layer extending from the second UV curable polymer layer opposite the first UV curable polymer layer, the third UV curable polymer layer extending to a top surface of the component at the component contact pad, the third UV curable polymer layer being formed on the second UV curable polymer layer after the second UV curable polymer layer is cured with the UV illumination, wherein the first UV curable polymer layer, the second UV curable polymer layer, and the third UV curable polymer layer have a stepwise configuration extending between the PCB contact pad and the component contact pad; and a conductive interconnect on each of the first UV curable polymer layer, the second UV curable polymer layer, and the third UV curable polymer layer, wherein the first UV curable polymer layer, the second UV curable polymer layer, and the third UV curable polymer layer form a loop configuration between the PCB contact pad and the component contact pad.

In Example 2, the subject matter of Example 1 includes, wherein the first UV curable polymer layer is formed at an edge of the PCB and the third UV curable polymer layer is formed at an edge of the component such that the bridge structure extends between the edge of the PCB at the PCB top surface and the component edge at the component top surface.

In Example 3, the subject matter of Example 2 includes, wherein the conductive interconnect extends beyond the first UV curable polymer layer, over a portion of the PCB, and contacts the PCB contact pad and the conductive interconnect extends beyond the third UV curable polymer layer, over a portion of the component, and contacts the component contact pad.

In Example 4, the subject matter of Examples 1-3 includes, wherein the first UV curable polymer layer is formed on a top surface of the PCB contact pad and the third UV curable polymer layer is formed on a top surface of the component contact pad such that the bridge structure extends from the PCB contact pad top surface to the component contact pad top surface.

In Example 5, the subject matter of Examples 1-4 includes, wherein the conductive interconnect is formed from conductive ink printed on the bridge structure.

In Example 6, the subject matter of Examples 1-5 includes, wherein the first UV curable layer is formed on a top surface of the PCB conductive trace and extends away from the PCB conductive trace top surface where the third UV curable polymer layer is higher than the first UV curable polymer layer and the bridge structure loops upwardly between the PCB top surface and the component top surface.

In Example 7, the subject matter of Examples 1-6 includes, wherein the PCB includes a cavity and the component is disposed in the cavity such that the first UV curable polymer layer is planar with the third UV curable polymer layer and the bridge structure loops between the first UV curable polymer layer and the third UV curable polymer layer.

In Example 8, the subject matter of Examples 1-7 includes, wherein an airgap is formed underneath the bridge structure.

Example 9 is a bridge structure that extends between a contact pad a printed circuit board (PCB) at a conductive trace of the PCB and a contact pad of a component disposed on the PCB, the bridge structure comprising: a first layer extending from a top surface of the conductive trace at the PCB contact pad; a second layer extending from the first layer opposite the PCB contact pad, the second layer being formed on the first layer; a third layer extending from the second layer opposite the first layer, the third layer extending to a top surface of the component at the component contact pad, the third layer being formed on the second layer, wherein the first layer, the second layer, and the third layer have a stepwise configuration extending between the PCB contact pad and the component contact pad; and a conductive interconnect on each of the first layer, the second layer, and the third layer, wherein the first layer, the second layer, and the third layer form a loop configuration between the PCB contact pad and the component contact pad.

In Example 10, the subject matter of Example 9 includes, wherein each of the first layer, the second layer, and the third layer are formed with a thixotropic ink.

In Example 11, the subject matter of Examples 9-10 includes, wherein each of the first layer, the second layer, and the third layer are formed with an ultraviolet (UV) curable polymer layer.

In Example 12, the subject matter of Examples 9-11 includes, wherein the PCB includes a cavity and the component is disposed in the cavity such that the first layer is planar with the third layer and the bridge structure loops between the first layer and the third layer.

In Example 13, the subject matter of Examples 9-12 includes, wherein an airgap is formed underneath the bridge structure.

In Example 14, the subject matter of Examples 9-13 includes, wherein the first layer is formed on a top surface of the PCB conductive trace and extends away from the PCB conductive trace top surface where the third layer is higher than the first layer and the bridge structure loops upwardly between the PCB top surface and the component top surface.

Example 15 is a bridge structure that extends between a contact pad a printed circuit board (PCB) at a conductive trace of the PCB and a contact pad of a component disposed on the PCB, the bridge structure comprising: a first layer extending from a top surface of the conductive trace at the PCB contact pad; a second layer extending from the first layer opposite the PCB contact pad, the second layer being formed on the first layer; a third layer extending from the second layer opposite the first layer, the third layer extending to a top surface of the component at the component contact pad, the third layer being formed on the second layer, wherein the first layer, the second layer, and the third layer have a stepwise configuration extending between the PCB contact pad and the component contact pad; and a conductive interconnect on each of the first layer, the second layer, and the third layer.

In Example 16, the subject matter of Example 15 includes, wherein the first layer, the second layer, and the third layer form a loop configuration between the PCB contact pad and the component contact pad.

In Example 17, the subject matter of Examples 15-16 includes, wherein the first layer, the second layer, and the third layer have a linear configuration between the PCB contact pad and the component contact pad.

In Example 18, the subject matter of Examples 15-17 includes, wherein each of the first layer, the second layer, and the third layer are formed from one of a thixotropic ink or an ultraviolet (UV) curable polymer layer.

In Example 19, the subject matter of Examples 15-18 includes, wherein the PCB includes a cavity and the component is disposed in the cavity such that the first layer is planar with the third layer and the bridge structure loops between the first layer and the third layer.

In Example 20, the subject matter of Examples 15-19 includes, wherein the first layer is formed on a top surface of the PCB conductive trace and extends away from the PCB conductive trace top surface where the third layer is higher than the first layer and the bridge structure loops upwardly between the PCB top surface and the component top surface.

Example 21 is an apparatus comprising means to implement of any of Examples 1-20.

Example 22 is a system to implement of any of Examples 1-20.

Example 23 is a method to implement of any of Examples 1-20.

Although teachings have been described with reference to specific example teachings, it will be evident that various modifications and changes may be made to these teachings without departing from the broader spirit and scope of the teachings. Accordingly, the specification and drawings are to be regarded in an illustrative rather than a restrictive sense. The accompanying drawings that form a part hereof, show by way of illustration, and not of limitation, specific teachings in which the subject matter may be practiced. The teachings illustrated are described in sufficient detail to enable those skilled in the art to practice the teachings disclosed herein. Other teachings may be utilized and derived therefrom, such that structural and logical substitutions and changes may be made without departing from the scope of this disclosure. This Detailed Description, therefore, is not to be taken in a limiting sense, and the scope of various teachings is defined only by the appended claims, along with the full range of equivalents to which such claims are entitled.

What is claimed is:

1. A bridge structure that extends between a contact pad a printed circuit board (PCB) at a conductive trace of the PCB and a contact pad of a component disposed on the PCB, the bridge structure comprising:
a first ultra-violet (UV) curable polymer layer extending from a top surface of the conductive trace at the PCB contact pad;
a second UV curable polymer layer extending from the first UV curable polymer layer opposite the PCB contact pad, the second UV curable polymer layer being formed on the first UV curable polymer layer after the first UV curable polymer layer is cured with UV illumination;
a third UV curable polymer layer extending from the second UV curable polymer layer opposite the first UV curable polymer layer, the third UV curable polymer layer extending to a top surface of the component at the component contact pad, the third UV curable polymer layer being formed on the second UV curable polymer layer after the second UV curable polymer layer is cured with the UV illumination, wherein the first UV curable polymer layer, the second UV curable polymer layer, and the third UV curable polymer layer have a stepwise configuration extending between the PCB contact pad and the component contact pad; and
a conductive interconnect on each of the first UV curable polymer layer, the second UV curable polymer layer, and the third UV curable polymer layer, wherein the first UV curable polymer layer, the second UV curable polymer layer, and the third UV curable polymer layer form a loop configuration between the PCB contact pad and the component contact pad.

2. The bridge structure of claim 1, wherein the first UV curable polymer layer is formed at an edge of the PCB and the third UV curable polymer layer is formed at an edge of the component such that the bridge structure extends between the edge of the PCB at the PCB top surface and the component edge at the component top surface.

3. The bridge structure of claim 2, wherein the conductive interconnect extends beyond the first UV curable polymer layer, over a portion of the PCB, and contacts the PCB contact pad and the conductive interconnect extends beyond the third UV curable polymer layer, over a portion of the component, and contacts the component contact pad.

4. The bridge structure of claim 1, wherein the first UV curable polymer layer is formed on a top surface of the PCB contact pad and the third UV curable polymer layer is formed on a top surface of the component contact pad such that the bridge structure extends from the PCB contact pad top surface to the component contact pad top surface.

5. The bridge structure of claim 1, wherein the conductive interconnect is formed from conductive ink printed on the bridge structure.

6. The bridge structure of claim 1, wherein the first UV curable layer is formed on a top surface of the PCB conductive trace and extends away from the PCB conductive trace top surface where the third UV curable polymer layer is higher than the first UV curable polymer layer and the bridge structure loops upwardly between the PCB top surface and the component top surface.

7. The bridge structure of claim 1, wherein the PCB includes a cavity and the component is disposed in the cavity such that the first UV curable polymer layer is planar with the third UV curable polymer layer and the bridge structure loops between the first UV curable polymer layer and the third UV curable polymer layer.

8. The bridge structure of claim 1, wherein an airgap is formed underneath the bridge structure.

9. A bridge structure that extends between a contact pad a printed circuit board (PCB) at a conductive trace of the PCB and a contact pad of a component disposed on the PCB, the bridge structure comprising:
a first layer extending from a top surface of the conductive trace at the PCB contact pad;
a second layer extending from the first layer opposite the PCB contact pad, the second layer being formed on the first layer;
a third layer extending from the second layer opposite the first layer, the third layer extending to a top surface of the component at the component contact pad, the third layer being formed on the second layer, wherein the first layer, the second layer, and the third layer have a stepwise configuration extending between the PCB contact pad and the component contact pad; and
a conductive interconnect on each of the first layer, the second layer, and the third layer, wherein the first layer, the second layer, and the third layer form a loop configuration between the PCB contact pad and the component contact pad.

10. The bridge structure of claim 9, wherein each of the first layer, the second layer, and the third layer are formed with a thixotropic ink.

11. The bridge structure of claim 9, wherein each of the first layer, the second layer, and the third layer are formed with an ultraviolet (UV) curable polymer layer.

12. The bridge structure of claim 9, wherein the PCB includes a cavity and the component is disposed in the cavity such that the first layer is planar with the third layer and the bridge structure loops between the first layer and the third layer.

13. The bridge structure of claim 9, wherein an airgap is formed underneath the bridge structure.

14. The bridge structure of claim 9, wherein the first layer is formed on a top surface of the PCB conductive trace and extends away from the PCB conductive trace top surface where the third layer is higher than the first layer and the bridge structure loops upwardly between the PCB top surface and the component top surface.

15. A bridge structure that extends between a contact pad a printed circuit board (PCB) at a conductive trace of the PCB and a contact pad of a component disposed on the PCB, the bridge structure comprising:
a first layer extending from a top surface of the conductive trace at the PCB contact pad;
a second layer extending from the first layer opposite the PCB contact pad, the second layer being formed on the first layer;
a third layer extending from the second layer opposite the first layer, the third layer extending to a top surface of the component at the component contact pad, the third layer being formed on the second layer, wherein the first layer, the second layer, and the third layer have a stepwise configuration extending between the PCB contact pad and the component contact pad; and
a conductive interconnect on each of the first layer, the second layer, and the third layer.

16. The bridge structure of claim 15, wherein the first layer, the second layer, and the third layer form a loop configuration between the PCB contact pad and the component contact pad.

17. The bridge structure of claim 15, wherein the first layer, the second layer, and the third layer have a linear configuration between the PCB contact pad and the component contact pad.

18. The bridge structure of claim 15, wherein each of the first layer, the second layer, and the third layer are formed from one of a thixotropic ink or an ultraviolet (UV) curable polymer layer.

19. The bridge structure of claim 15, wherein the PCB includes a cavity and the component is disposed in the cavity such that the first layer is planar with the third layer and the bridge structure loops between the first layer and the third layer.

20. The bridge structure of claim 15, wherein the first layer is formed on a top surface of the PCB conductive trace and extends away from the PCB conductive trace top surface where the third layer is higher than the first layer and the bridge structure loops upwardly between the PCB top surface and the component top surface.
